(19) United States
(12) Patent Application Publication
(10) Pub. No.: US 2025/0294883 A1
(43) Pub. Date: Sep. 18, 2025

(54) DISPLAY DEVICE AND METHOD FOR MANUFACTURING SAME

(71) Applicant: Sharp Display Technology Corporation, Kameyama City, Mie (JP)

(72) Inventors: Shunsuke KOBAYASHI, Kameyama City, Mie (JP); Shogo MURASHIGE, Kameyama City, Mie (JP); Izumi ISHIDA, Kameyama City, Mie (JP)

(21) Appl. No.: 18/862,667

(22) PCT Filed: Jun. 30, 2022
(86) PCT No.: PCT/JP2022/026198

§ 371 Date: Nov. 4, 2024

(51) Int. Cl. H10D 86/60; H10D 30/67; H10D 86/01; H10D 86/40; H10K 59/80

(52) U.S. Cl. CPC H10D 86/60; H10D 30/6736; H10D 86/0221; H10D 86/423; H10K 59/873

(57) ABSTRACT

A display device includes a TFT layer having a stack of, in sequence, a first inorganic insulating film composed of a first inorganic material, a second inorganic insulating film composed of a second inorganic material different from the first inorganic material, a first metal film composed of a metal material containing molybdenum a principal component, an oxide semiconductor film composed of an oxide semiconductor, a gate insulating film, and a second metal film. The second inorganic insulating film is provided between the first inorganic insulating film and a first electrode formed from the first metal film, and between the first inorganic insulating film and a second electrode formed from the first metal film.

### TECHNICAL FIELD

The present disclosure relates to a display device and a method for manufacturing the same.

### BACKGROUND ART

Attention has been recently drawn to self-emission organic EL display devices incorporating organic electroluminescence (hereinafter, also referred to as EL) elements, as display devices alternative to liquid crystal displays. Such an organic EL display device has a plurality of thin-film transistors (hereinafter, also referred to as “TFTs”) provided for each subpixel, which is the minimum unit of an image. Here, well-known examples of a semiconductor layer constituting TFTs include a semiconductor layer composed of high-mobility polysilicon, and a semiconductor layer composed of an oxide semiconductor with a small leakage current (hereinafter, referred to as an “oxide semiconductor layer”), such as an In—Ga—Zn—O semiconductor.

For example, Patent Literature 1 proposes, as a TFT having such a semiconductor layer, a TFT having a gate electrode and/or a source/drain electrode formed from a copper wire with favorable adhesion to a substrate and a semiconductor film, and a display device incorporating such TFTs.

### CITATION LIST

### Patent Literature

Patent Literature 1: Japanese Unexamined Patent Application Publication No. 2013-153093

### SUMMARY

### Technical Problem

By the way, in a TFT of bottom-contact structure in which a metal layer (molybdenum layer) composed of molybdenum is provided under the oxide semiconductor layer, since the molybdenum layer and the oxide semiconductor layer are formed in the same layer, an inorganic insulating film (silicon oxide film) composed of silicon oxide is usually provided directly under the oxide semiconductor layer in order to prevent electrical continuity. In this structure, oxygen is desorbed from the silicon oxide film through annealing in a subsequent step after the formation of the silicon oxide film, thereby possibly causing the molybdenum layer to oxidize. In this case, the adhesion between the molybdenum layer and the silicon oxide film thereunder is lowered, thereby causing a film blister (film peeling) at the interface between the molybdenum layer and silicon oxide film to possibly cause a break (TFT failure) in the oxide semiconductor layer to thus cause a display failure, such as a display bright spot.

On the other hand, in a structure in which an inorganic insulating film composed of silicon nitride (silicon nitride film) with favorable adhesion to a molybdenum layer is provided under the oxide semiconductor layer, the silicon nitride film and the oxide semiconductor layer are in contact together. In this case, hydrogen desorbed from the silicon nitride film reaches the oxide semiconductor layer, thereby possibly causing a depression shift, in which a TFT's threshold voltage shifts to the negative side.

It is noted that the TFTs and display device described in Patent Literature 1 are based on the premise that a copper wire is provided therein, and that Patent Literature 1 is silent about the adhesion between the molybdenum layer and the substrate or semiconductor film.

The disclosure has been made in view of this problem. It is an object of the disclosure to improve the adhesion between a metal layer containing molybdenum as a principal component and a substrate in a display device provided with a TFT having a semiconductor layer composed of an oxide semiconductor, and to prevent a depression shift in this display device.

### Solution to Problem

To achieve the above object, a display device according to the disclosure includes the following: a base substrate, and a thin-film transistor layer provided on the base substrate, and having a stack of, in sequence, a first inorganic insulating film composed of a first inorganic material, a second inorganic insulating film composed of a second inorganic material different from the first inorganic material, a first metal film composed of a metal material containing molybdenum as a principal component, an oxide semiconductor film composed of an oxide semiconductor, a gate insulating film, and a second metal film. The thin-film transistor layer includes a thin-film transistor provided for each of subpixels constituting a display region. The thin-film transistor includes the following: a first electrode and a second electrode formed from the first metal film, and provided on the first inorganic insulating film so as to extend in parallel with each other in a first direction; an oxide semiconductor layer formed from the oxide semiconductor film, and provided on the first inorganic insulating film and the first and second electrodes so as to extend in a second direction intersecting with the first and second electrodes; and a gate electrode formed from the second metal film, and provided on the oxide semiconductor layer with the gate insulating film interposed between the gate electrode and the oxide semiconductor layer so as to extend in the first direction. The second inorganic insulating film is provided between the first inorganic insulating film and the first electrode, and between the first inorganic insulating film and the second electrode.

A method for manufacturing a display device according to the disclosure is a method for manufacturing a display device including the following: a base substrate, and a thin-film transistor layer provided on the base substrate, and having a thin-film transistor provided for each of subpixels constituting a display region. The method includes a step of forming the thin-film transistor layer onto the base substrate. The step of forming the thin-film transistor layer includes the following: a step of forming insulating films comprising sequentially forming a first inorganic insulating film composed of a first inorganic material, and a second inorganic insulating film composed of a second inorganic material different from the first inorganic material; a step of forming a first metal layer that is forming a first electrode and a second electrode individually so as to extend in parallel with each other in a first direction, by forming a first metal film composed of a metal material containing molybdenum as a principal component onto a substrate surface where the first and second inorganic insulating films are formed, followed by patterning the first metal film; a step of forming an oxide semiconductor layer so as to extend in a second direction intersecting with the first and second electrodes, by forming an oxide semiconductor film composed of an oxide semiconductor onto the substrate surface where the first and second electrodes are formed, followed by patterning the oxide semiconductor film; a step of forming a gate insulating film onto the substrate surface where the oxide semiconductor layer is formed, so as to extend in the first direction; and a step of forming a gate electrode onto the gate insulating film by forming a second metal film onto the substrate surface where the gate insulating film is formed, followed by patterning the second metal film. In the step of forming the first metal layer, the second inorganic insulating film is caused to remain between the first inorganic insulating film and the first electrode, and between the first inorganic insulating film and the second electrode by etching the first metal film, followed by etching the second inorganic insulating film.

Further, in a method for manufacturing a display device according to the disclosure, the display device includes the following: a base substrate, and a thin-film transistor layer provided on the base substrate, and having a thin-film transistor provided for each of subpixels constituting a display region. The method includes a step of forming the thin-film transistor layer onto the base substrate. The step of forming the thin-film transistor layer includes the following: a step of forming insulating films that is sequentially forming a first inorganic insulating film composed of a first inorganic material, and a second inorganic insulating film composed of a second inorganic material different from the first inorganic material; a step of forming a first metal layer that is forming a first electrode and a second electrode individually so as to extend in parallel with each other in a first direction, by forming a first metal film composed of a metal material containing molybdenum as a principal component onto a substrate surface where the first and second inorganic insulating films are formed, followed by patterning the first metal film; a step of patterning the second inorganic insulating film; a step of forming an oxide semiconductor layer so as to extend in a second direction intersecting with the first and second electrodes, by forming an oxide semiconductor film composed of an oxide semiconductor onto the substrate surface where the first and second electrodes are formed, and where the second inorganic insulating film is patterned, followed by patterning the oxide semiconductor film; a step of forming a gate insulating film onto the substrate surface where the oxide semiconductor layer is formed, so as to extend in the first direction; and a step of forming a gate electrode onto the gate insulating film by forming a second metal film onto the substrate surface where the gate insulating film is formed, followed by patterning the second metal film. The oxide semiconductor layer includes the following: a first conductor region and a second conductor region defined so as to be spaced from each other, and electrically connected to the first electrode and the second electrode, respectively; and a channel region defined between the first and second conductor regions, and overlapping the gate electrode in a plan view. In the step of patterning the second inorganic insulating film, the second inorganic insulating film is caused to remain between the first inorganic insulating film and the first electrode, and between the first inorganic insulating film and the second electrode, and an extending portion of the second inorganic insulating film is caused to remain between the first inorganic insulating film and the first conductor region, and between the first inorganic insulating film and the second conductor region so as to extend in the second direction along the oxide semiconductor layer, and such that an end of the extending portion adjacent to the channel region is spaced from the channel region.

### Advantageous Effect of Disclosure

The disclosure can improve the adhesion between a metal layer containing molybdenum as a principal component and a substrate in a display device provided with a TFT having a semiconductor layer composed of an oxide semiconductor and can prevent a depression shift in this display device.

### BRIEF DESCRIPTION OF DRAWINGS

FIG. 1 is a plan view of the schematic configuration of an organic EL display device according to a first embodiment of the disclosure.

FIG. 2 is a plan view of a display region of the organic EL display device according to the first embodiment of the disclosure.

FIG. 3 is an enlarged plan view on the periphery of a first TFT, which constitutes the organic EL display device according to the first embodiment of the disclosure.

FIG. 4 is a cross-sectional view of the display region of the organic EL display device according to the first embodiment of the disclosure, taken along line IV-IV in FIG. 3.

FIG. 5 is an equivalent circuit diagram of a TFT layer, which constitutes the organic EL display device according to the first embodiment of the disclosure.

FIG. 6 is a cross-sectional view of an organic EL layer, which constitutes the organic EL display device according to the first embodiment of the disclosure.

FIG. 7 is an enlarged plan view on the periphery of a first TFT, which constitutes the organic EL display device according to a second embodiment of the disclosure, and corresponds to FIG. 3.

FIG. 8 is a cross-sectional view of the display region of the organic EL display device according to the second embodiment of the disclosure, taken along line VIII-VIII in FIG. 7 and corresponds to FIG. 4.

### DESCRIPTION OF EMBODIMENTS

Embodiments of the disclosure will be detailed on the basis of the drawings. It is noted that the disclosure is not limited to the following embodiments.

### First Embodiment

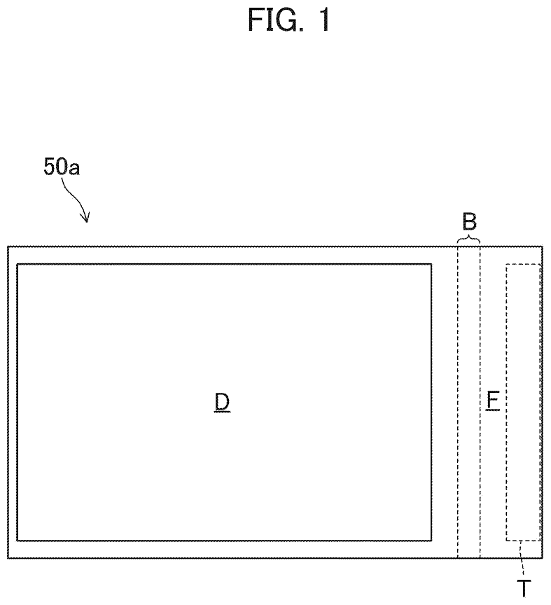

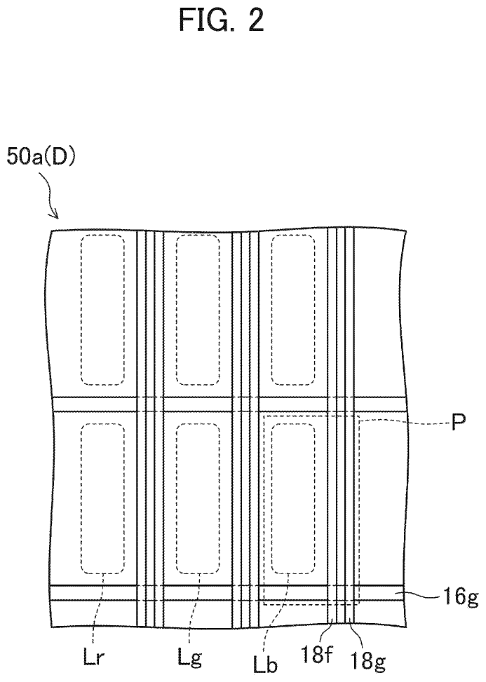

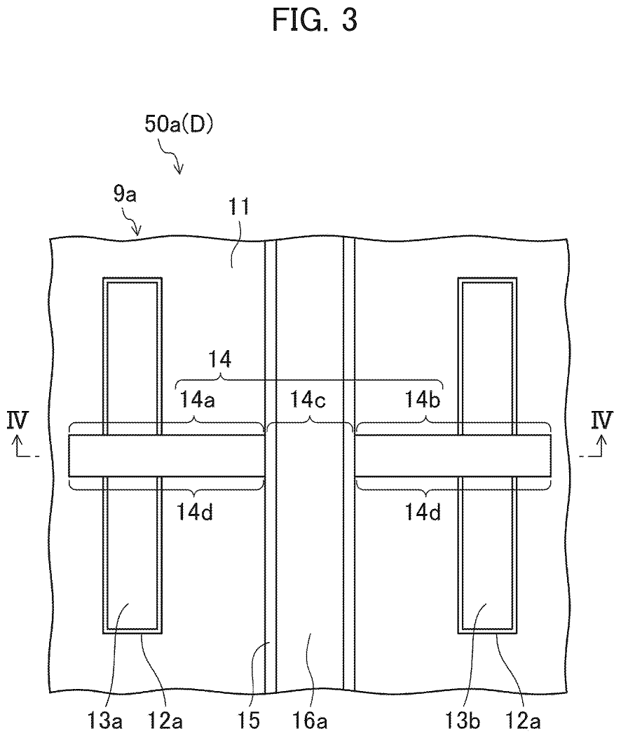

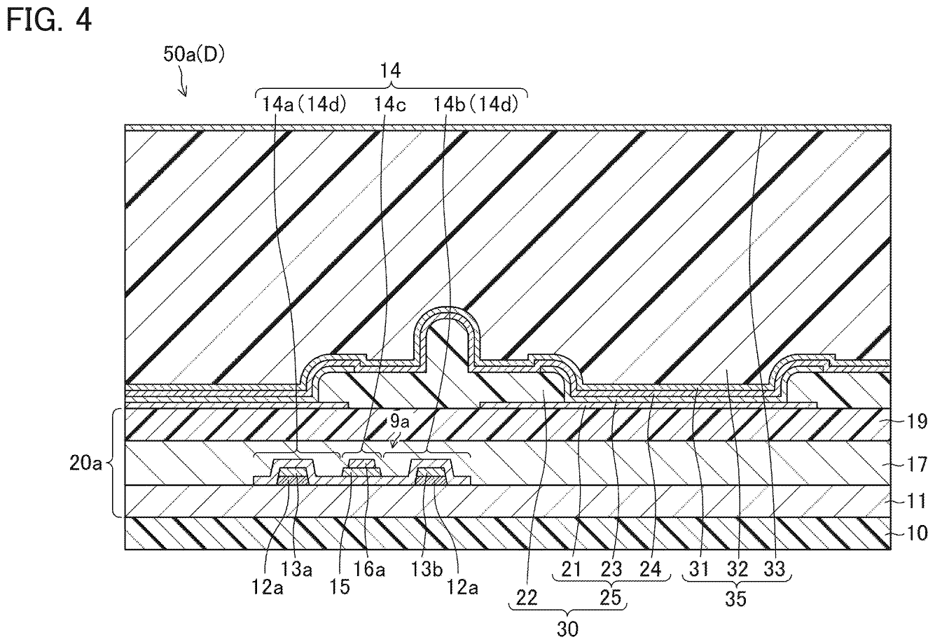

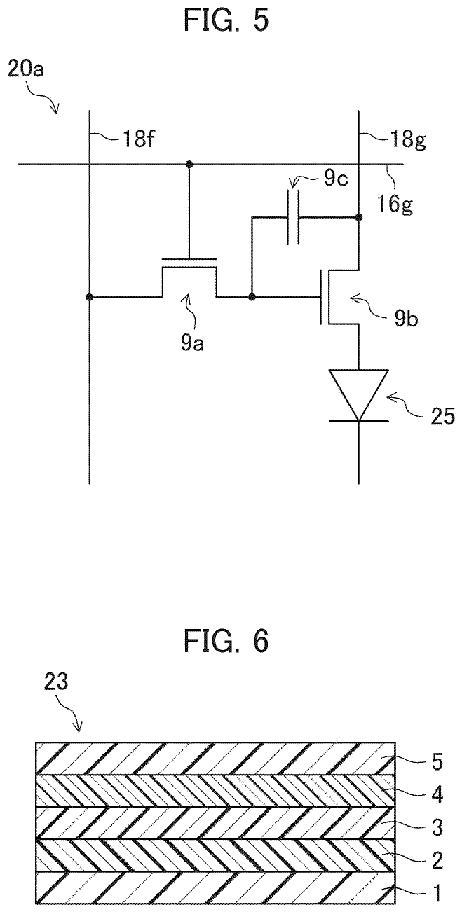

FIG. 1 to FIG. 6 illustrate a display device according to a first embodiment of the disclosure. It is noted that the following embodiments will describe an organic EL display device provided with an organic EL element by way of example, as a display device provided with a light-emitting element. Here, FIG. 1 is a plan view of the schematic configuration of an organic EL display device 50a according to this embodiment. FIG. 2 is a plan view of a display region D of the organic EL display device 50a. FIG. 3 is an enlarged plan view on the periphery of a first TFT 9a, which constitutes the organic EL display device 50a. FIG. 4 is a cross-sectional view of the display region D of the organic EL display device 50a, taken along line IV-IV in FIG. 3. FIG. 5 is an equivalent circuit diagram of a TFT layer 20a, which constitutes the organic EL display device 50a. FIG. 6 is a cross-sectional view of an organic EL layer 23, which constitutes the organic EL display device 50a.

As illustrated in FIG. 1, the organic EL display device 50a has the display region D provided in the form of, for instance, a rectangle and provided for image display, and a frame region F provided in the form of a frame around the display region D. It is noted that although this embodiment describes the rectangular display region D by way of example, this rectangular shape includes substantially rectangular shapes, such as a shape with an arc-shaped side, a shape with an arc-shaped corner, and a shape with part of a side being cut.

The display region D includes a plurality of subpixels P arranged in matrix, as illustrated in FIG. 2. Further, as illustrated in FIG. 2, a subpixel P having a red light-emitting region Lr for red display, a subpixel P having a green light-emitting region Lg for green display, and a subpixel P having a blue light-emitting region Lb for blue display, for instance are provided in the display region D so as to be adjacent to one another. It is noted that the display region D is structured such that for instance, three adjacent subpixels P having the red light-emitting region Lr, green light-emitting region Lg, and blue light-emitting region Lb constitute a single pixel. It is also noted that the arrangement of the subpixels P is non-limiting; examples include a Pen Tile matrix and a stripe matrix.

The frame region F includes a terminal section T provided at the right end in FIG. 1 so as to extend in one direction (the longitudinal direction of the drawing). The frame region F also includes, as illustrated in FIG. 1, a bending section B provided between the display region D and the terminal section T so as to extend in one direction (the longitudinal direction of the drawing); here, the bending section B is, for instance, 180° (U-shape) bendable about a bending axis, which is in the longitudinal direction of the drawing.

As illustrated in FIG. 4, the organic EL display device 50a includes a resin substrate 10 provided as a base substrate, and the TFT layer 20a provided on the resin substrate 10.

The resin substrate 10 is composed of a material, such as polyimide resin.

The TFT layer 20a includes the following as illustrated in FIGS. 3 and 4: a first inorganic insulating film 11 provided on the resin substrate 10; a plurality of first TFTs 9a, a plurality of second TFTs 9b (see FIG. 5), and a plurality of capacitors 9c (see FIG. 5) provided on the first inorganic insulating film 11 and each provided in a corresponding one of the subpixels P; and a flattening film 19 provided over the first TFTs 9a, second TFTs 9b, and capacitors 9c. Here, the TFT layer 20a includes, as illustrated in FIGS. 2 and 5, a plurality of gate lines 16g provided as a second metal layer so as to extend in parallel with each other in the lateral direction of the drawings. The TFT layer 20a also includes, as illustrated in FIGS. 2 and 5, a plurality of source lines 18f provided as a third metal layer so as to extend in parallel with each other in a direction intersecting with (orthogonal to) the plurality of gate lines 16g, i.e., in the longitudinal direction of the drawings. The TFT layer 20a also includes, as illustrated in FIGS. 2 and 5, a plurality of power supply lines 18g provided as the third metal layer so as to extend in parallel with each other in the longitudinal direction of the drawings. Each of the power supply lines 18g is provided so as to be adjacent to a corresponding one of the source lines 18f, as illustrated in FIG. 2. Here, the TFT layer 20a is structured such that as illustrated in FIGS. 3 and 4, the first inorganic insulating film 11, a second inorganic insulating film 12a, a first metal film constituting a first metal layer, an oxide semiconductor film constituting an oxide semiconductor layer 14, a gate insulating film 15, a second metal film constituting the second metal layer, such as the gate lines 16g, an interlayer insulating film 17, a third metal film constituting the third metal layer, such as the source lines 18f and power supply lines 18g, and the flattening film 19, all of which will be described later on, are stacked sequentially on the resin substrate 10.

The first inorganic insulating film 11 is composed of a first inorganic material containing silicon oxide (SiO₂) as a principal component (which is the material of the first inorganic insulating film 11; hereinafter, also simply referred to as a “SiO₂ film”). It is noted that a principal component in the Description means a component whose content in a constituent material exceeds 50 mass %, and that a principal component may be a component of 100 mass % (containing only a principal component).

The first TFT 9a in each subpixel P is electrically connected to the corresponding gate line 16g and source line 18f, as illustrated in FIG. 5. The first TFT 9a includes the following as illustrated in FIGS. 3 and 4: a source electrode 13a (first metal layer) as a first electrode, and a drain electrode 13b (first metal layer) as a second electrode; the oxide semiconductor layer 14; and a gate electrode 16a (second metal layer) provided with the gate insulating film 15 interposed therebetween.

The second TFT 9b in each subpixel P is electrically connected to the corresponding first TFT 9a and power supply line 18g, as illustrated in FIG. 5. Like the first TFT 9a, the second TFT 9b includes a source electrode (13a) as well as a drain electrode (13b) (first metal layer), an oxide semiconductor layer (14), and a gate electrode (16a) provided with a gate insulating film (15) interposed therebetween.

The source electrode 13a and the drain electrode 13b are individually provided so as to extend in the longitudinal direction (a first direction) of the drawing, as illustrated in FIG. 3. The source electrode 13a and the drain electrode 13b are electrically connected to, but not limited to, the source line 18f, the power supply line 18g, and a third electrode 21 via contact holes (not shown) formed in, for instance, an interlayer insulating film 17. It is noted that the source electrode 13a and the drain electrode 13b are formed from the first metal film. The first metal film is composed of a metal material containing molybdenum (Mo) as a principal component (the material of the source electrode 13a and drain electrode 13b; hereinafter, also simply referred to as a “Mo film”). The first metal film may be, for example, a Mo monolayer film or a metal laminated film of Mo (upper layer), Al (middle layer) and Mo (lower layer) or other combinations.

As illustrated in FIGS. 3 and 4, the oxide semiconductor layer 14 is formed of an oxide semiconductor, such as an In—Ga—Zn—O oxide semiconductor, and is provided in an island shape so as to extend in the lateral direction (a second direction orthogonal to the first direction) of the drawings. The oxide semiconductor layer 14 includes the following as illustrated in FIGS. 3 and 4: a source region (first conductor region) 14a and a drain region (second conductor region) 14b defined so as to be spaced from each other; and a channel region 14c defined between the source region 14a and the drain region 14b. As illustrated in FIG. 3, the source region 14a and the drain region 14b intersect with and are electrically connected to the source electrode 13a and the drain electrode 13b, respectively. Here, as illustrated in FIG. 4, the oxide semiconductor layer 14 has a bottom-contact structure, which is such a structure as to extend astride each of the source electrode 13a and drain electrode 13b in the source region 14a and drain region 14b. In this structure, the oxide semiconductor layer 14 is formed in the same layer as the source electrode 13a and drain electrode 13b. Here, the In—Ga—Zn—O semiconductor is a ternary oxide of indium (In), gallium (Ga), and zinc (Zn) and may contain In, Ga, and Zn at any ratio (composition ratio). Further, the In—Ga—Zn—O semiconductor may be amorphous or crystalline. It is noted that a preferable crystalline In—Ga—Zn—O semiconductor is a crystalline In—Ga—Zn—O semiconductor whose c-axis is nearly perpendicular to a layer surface. It is also noted that other kinds of oxide semiconductor may be contained instead of an In—Ga—Zn—O semiconductor. The other kinds of oxide semiconductor may include an In—Sn—Zn—O semiconductor (e.g., In₂O₃—SnO₂—ZnO, InSnZnO) for instance. Here, the In—Sn—Zn—O semiconductor is a ternary oxide of indium (In), tin (Sn), and zinc (Zn). Further, the other kinds of oxide semiconductor may include, but not limited to, an In—Al—Zn—O semiconductor, an In—Al—Sn—Zn—O semiconductor, a Zn—O semiconductor, an In—Zn—O semiconductor, a Zn—Ti—O semiconductor, a Cd—Ge—O semiconductor, a Cd—Pb—O semiconductor, cadmium oxide (CdO), a Mg—Zn—O semiconductor, an In—Ga—Sn—O semiconductor, an In—Ga—O semiconductor, a Zr—In—Zn—O semiconductor, a Hf—In—Zn—O semiconductor, an Al—Ga—Zn—O semiconductor, a Ga—Zn—O semiconductor, an In—Ga—Zn—Sn—O semiconductor, InGaO₃(ZnO)₅, magnesium zinc oxide (MgₓZn₁₋ₓO), and cadmium zinc oxide (CdₓZn₁₋ₓO). It is noted that a usable Zn—O semiconductor is an amorphous semiconductor of ZnO with one or more kinds of impurity elements selected from among, but not limited to, a Group I element, a Group XIII element, a Group XIV element, a Group XV element, and a Group XVII element being added thereto, a polycrystalline semiconductor of such ZnO, or a crystallite semiconductor of such ZnO including amorphous and polycrystalline substances; alternatively, a usable Zn—O semiconductor is a ZnO semiconductor without any impurity elements being added thereto.

As illustrated in FIG. 3, the gate insulating film 15 is provided so as to extend in the first direction and intersects with the oxide semiconductor layer 14 in the channel region 14c. As illustrated in FIG. 4, the gate insulating film 15 is provided on the oxide semiconductor layer 14 so as to overlap the channel region 14 in plan view. The gate insulating film 15 is formed from an inorganic insulating monolayer film or inorganic insulating multilayer film of a material, such as silicon nitride (SiNx, where x is a positive number), silicon oxide (SiO₂), or silicon oxide nitride (SiON). Among them, the gate insulating film 15 is preferably formed from a silicon oxide film.

As illustrated in FIG. 3, the gate electrode 16a is provided so as to overlap the gate insulating film 15 in plan view. That is, like the gate insulating film 15, the gate electrode 16a is provided so as to extend in the first direction and intersects with the oxide semiconductor layer 14 in the channel region 14c. As illustrated in FIG. 4, the gate electrode 16a is provided on the gate insulating film 15 so as to overlap the channel region 14c in plan view. The gate electrode 16a is configured to control the electrical continuity between the source region 14a and drain region 14b of the oxide semiconductor layer 14. It is noted that like the gate lines 16g, the gate electrode 16a is formed from the second metal film. The second metal film is formed from a monolayer film of a metal, such as molybdenum (Mo), titanium (Ti,), aluminum (Al), copper (Cu), or tungsten (W), or is composed of a multilayer film of metals, such as Mo (upper layer)—Al (middle layer)—Mo (lower layer), Ti—Al—Ti, Al (upper layer)—Ti (lower layer), Cu—Mo, or Cu—Ti. Among them, the second metal film is preferably formed from a metal multilayer film of Ti—Al—Ti.

Here, the organic EL display device 50a includes a second inorganic insulating film 12a under (directly under) the source electrode 13a and the drain electrode 13b, as illustrated in FIG. 4. The second inorganic insulating film 12a is provided between the first inorganic insulating film 11 and the source electrode 13a, and between the first inorganic insulating film 11 and the drain electrode 13b. In other words, the source electrode 13a and the drain electrode 13b are provided on the second inorganic insulating film 12a. As described, the region in which th source electrode 13a and the drain electrode 13b overlap in plan view has a stack of, in sequence, the first inorganic insulating film 11 and the second inorganic insulating film 12a.

The second inorganic insulating film 12a is provided so as to extend in the first direction along the source electrode 13a and the drain electrode 13b, as illustrated in FIG. 3. The second inorganic insulating film 12a overlaps the whole of the source electrode 13a and the whole of the drain electrode 13b in plan view. That is, the second inorganic insulating film 12a is provided with a size (area) equal to or larger than the shapes of the source electrode 13a and drain electrode 13b. Further, the second inorganic insulating film 12a overlaps the source region 14a and drain region 14b of the oxide semiconductor layer 14, as illustrated in FIG. 3.

It is noted that the second inorganic insulating film 12a is composed of a second inorganic material containing, as a principal component, silicon nitride (SiNx, where x is a positive number; the material of the second inorganic insulating film 12a; hereinafter, also simply referred to as a “SiNx film”), which is different from the first inorganic material. A SiNx film has favorable adhesion to a Mo film.

As described, the organic EL display device 50a is structured such that the second inorganic insulating film 12a, which is formed from a SiNx film, is interposed between the first inorganic insulating film 11, which is formed from a SiO₂ film, and the source electrode 13a as well as the drain electrode 13b, both of which are formed from a Mo film. In this structure, the source electrode 13a and the drain electrode 13b (thereunder) are in contact with the second inorganic insulating film 12a but are not in contact with the first inorganic insulating film 11. It is noted that the source region 14a and drain region 14b overlapping the second inorganic insulating film 12a (as well as the source electrode 13a and drain electrode 13b) in plan view have a low resistance as a result of a reduction reaction resulting from hydrogen diffusion caused by a heat treatment in a subsequent step after a step of forming an oxide semiconductor layer, which will be described later on. To be specific, as illustrated in FIGS. 3 and 4, a low-resistance region 14d is formed in the source region 14a and drain region 14b disposed directly over the second inorganic insulating film 12a (as well as the source electrode 13a and drain electrode 13b).

It is noted that as illustrated in FIGS. 3 and 4, the organic EL display device 50a has no second inorganic insulating film 12a under the oxide semiconductor layer 14 except the portions overlapping the source electrode 13a and drain electrode 13b in plan view. To be specific, there is no second inorganic insulating film 12a in a region overlapping the channel region 14c in plan view. The channel region 14c (thereunder) is thus in contact with the first inorganic insulating film 11.

The capacitor 9c in each subpixel P is electrically connected to the corresponding first TFT 9a and power supply line 18g, as illustrated in FIG. 5. Here, the capacitor 9c includes, for example, a lower conductive layer (not shown) formed from the second metal film, an upper conductive layer (not shown) formed from the third metal film, and the interlayer insulating film 17 provided between these lower conductive layer and upper conductive layer. It is noted that the upper conductive layer is electrically connected to the power supply lines 18g.

The flattening film 19 has a flat surface in the display region D and is composed of, but not limited to, an organic resin material, such as polyimide resin.

The organic EL display device 50a includes the following as illustrated in FIG. 4: an organic EL element layer 30 provided as a light-emitting element layer on the TFT layer 20a; and a sealing film 35 provided so as to cover the organic EL element layer 30.

As illustrated in FIG. 4, the organic EL element layer 30 includes a plurality of organic EL elements 25 as a plurality of light-emitting elements arranged in matrix in correspondence with the plurality of subpixels P.

The organic EL elements 25 include the following as illustrated in FIG. 4: the third electrode 21 provided on the flattening film 19 in each subpixel P; the organic EL layer 23 provided on the third electrode 21 in each subpixel P; and a fourth electrode 24 provided on the organic EL layer 23 and shared among the plurality of subpixels P.

As illustrated in FIG. 4, the third electrode 21 is electrically connected to the drain electrode 13b of the second TFT 9b in each subpixel P via a contact hole formed in the flattening film 19. Moreover, the third electrode 21 has the function of injecting holes (positive holes) into the organic EL layer 23. Moreover, the third electrode 21 is more desirably made of a material having a small work function in order to improve the efficiency of hole injection into the organic EL layer 23. Here, the third electrode 21 is composed of metal, including silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Moreover, the third electrode 21 may be composed of, for instance, alloy of astatine (At) and astatine oxide (AtO₂). Furthermore, the third electrode 21 may be composed of, for instance, conductive oxide, including tin oxide (SnO), zinc oxide (ZnO), indium tin oxide (ITO), and indium zinc oxide (IZO). Moreover, the third electrode 21 may be formed by stacking multiple layers composed of the above materials. It is noted that examples of a compound material having a large work function include indium tin oxide (ITO) and indium zinc oxide (IZO).

Further, as illustrated in FIG. 4, the third electrode 21 has a perimeter covered with an edge cover 22 provided in a lattice shape and shared among the plurality of subpixels P. As illustrated in FIG. 4, part of the surface of the edge cover 22 protrudes upward in the drawing to constitute pixel photo-spacers provided in the form of islands. Examples of the material of the edge cover 22 include photosensitive positive resin materials, such as polyimide resins, acrylic resins, polysiloxane resins, and novolak resins, as well as a polysiloxane spin-on-glass (SOG) material

The organic EL layer 23 is provided as a light-emitting functional layer and includes, as illustrated in FIG. 6, a hole injection layer 1, a hole transport layer 2, an emission layer 3, an electron transport layer 4, and an electron injection layer 5 sequentially provided on the third electrode 21.

The hole injection layer 1 is also called an anode buffer layer and has the function of bringing the energy levels of the third electrode 21 and organic EL layer 23 close to each other to improve the efficiency of hole injection from the third electrode 21 into the organic EL layer 23. Here, examples of the material of the hole injection layer 1 include a triazole derivative, an oxadiazole derivative, an imidazole derivative, a polyarylalkane derivative, a pyrazoline derivative, a phenylenediamine derivative, an oxazole derivative, a styrylanthracene derivative, a fluorenone derivative, a hydrazone derivative, and a stilbene derivative.

The hole transport layer 2 has the function of improving the efficiency of hole transport from the third electrode 21 to the organic EL layer 23. Here, examples of the material of the hole transport layer 2 include a porphyrin derivative, an aromatic tertiary amine compound, a styrylamine derivative, polyvinylcarbazole, poly-p-phenylenevinylene, polysilane, a triazole derivative, an oxadiazole derivative, an imidazole derivative, a polyarylalkane derivative, a pyrazoline derivative, a pyrazolone derivative, a phenylenediamine derivative, an arylamine derivative, an amine-substituted chalcone derivative, an oxazole derivative, a styrylanthracene derivative, a fluorenone derivative, a hydrazone derivative, a stilbene derivative, hydrogenated amorphous silicon, hydrogenated amorphous silicon carbide, zinc sulfide, and zinc selenide.

The emission layer 3 is a region in which a hole and an electron are respectively injected from the third electrode 21 and fourth electrode 24 applied with voltage, and in which the hole and electron recombine together. Here, the emission layer 3 is made of a material having high efficiency of light emission. Moreover, examples of the material of the emission layer 3 include a metal oxinoid compound [8-hydroxyquinoline metal complex], a naphthalene derivative, an anthracene derivative, a diphenylethylene derivative, a vinyl acetone derivative, a triphenylamine derivative, a butadiene derivative, a coumarin derivative, a benzoxazole derivative, an oxadiazole derivative, an oxazole derivative, a benzimidazole derivative, a thiadiazole derivative, a benzthiazole derivative, a styryl derivative, a styrylamine derivative, a bisstyrylbenzene derivative, a trisstyrilbenzene derivative, a perylene derivative, a perynone derivative, an aminopyrene derivative, a pyridine derivative, a rhodamine derivative, an acridine derivative, phenoxazone, a quinacridone derivative, rubrene, poly-p-phenylenevinylene, and polysilane.

The electron transport layer 4 has the function of moving electrons to the emission layer 3 efficiently. Here, examples of the material of the electron transport layer 4 include organic compounds, such as an oxadiazole derivative, a triazole derivative, a benzoquinone derivative, a naphthoquinone derivative, an anthraquinone derivative, a tetracyanoanthraquinodimethane derivative, a diphenoquinone derivative, a fluorenone derivative, a silole derivative, and a metal oxinoid compound.

The electron injection layer 5 has the function of bringing the energy levels of the fourth electrode 24 and organic EL layer 23 close to each other to improve the efficiency of electron injection from the fourth electrode 24 into the organic EL layer 23. This function enables a voltage for driving the organic EL element 25 to be lowered. It is noted that the electron injection layer 5 is also called a cathode buffer layer. Here, examples of the material of the electron injection layer 5 include inorganic alkali compounds, such as lithium fluoride (LiF), magnesium fluoride (MgF₂), calcium fluoride (CaF₂), strontium fluoride (SrF₂), and barium fluoride (BaF₂), as well as aluminum oxide (Al₂O₃) and strontium oxide (SrO).

The fourth electrode 24 is provided so as to cover the organic EL layer 23 and edge cover 22 in each subpixel P, as illustrated in FIG. 4. Moreover, the fourth electrode 24 has the function of injecting electrons into the organic EL layer 23. Moreover, the fourth electrode 24 is more desirably made of a material having a small work function in order to improve the efficiency of electron injection into the organic EL layer 23. Here, examples of the material of the fourth electrode 24 include silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). Moreover, the fourth electrode 24 may be made of, for instance, alloy of magnesium (Mg) and copper (Cu), alloy of magnesium (Mg) and silver (Ag), alloy of sodium (Na) and potassium (K), alloy of astatine (At) and astatine oxide (AtO₂), alloy of lithium (Li) and aluminum (Al), alloy of lithium (Li), calcium (Ca) and aluminum (Al), or alloy of lithium fluoride (LiF), calcium (Ca) and aluminum (Al). Moreover, the fourth electrode 24 may be made of conductive oxide, such as tin oxide (SnO), zinc oxide (ZnO), indium tin oxide (ITO), or indium zinc oxide (IZO). Moreover, the fourth electrode 24 may be formed by stacking multiple layers composed of the above materials. It is noted that examples of the material having a small work function include magnesium (Mg), lithium (Li), lithium fluoride (LiF), magnesium (Mg)—copper (Cu), magnesium (Mg)—silver (Ag), sodium (Na)—potassium (K), lithium (Li)—aluminum (Al), lithium (Li)—calcium (Ca)—aluminum (Al), and lithium fluoride (LiF)—calcium (Ca)—aluminum (Al).

The sealing film 35 is provided on the organic EL element layer 30 so as to cover the individual organic EL elements 25, as illustrated in FIG. 4. Here, the sealing film 35 includes the following as illustrated in FIG. 4: a first inorganic sealing film 31 provided so as to cover the fourth substrate 24; an organic sealing film 32 provided on the first inorganic sealing film 31; and a second inorganic sealing film 33 provided so as to cover the organic sealing film 32, and the sealing film 35 has the function of protecting the organic sealing film 23 from water, oxygen, and other foreign substances. Here, the first inorganic sealing film 31 and the second inorganic sealing film 33 are composed of an inorganic material, including silicon oxide (SiO₂), aluminum oxide (Al₂O₃), silicon nitride (SiNx, where x is a positive number) such as trisilicon tetranitride (Si₃N₄), and silicon carbonitride (SiCN). Further, the organic sealing film 32 is composed of an organic material, including acrylic resin, polyurea resin, parylene resin, polyimide resin, and polyamide resin.

A method for manufacturing the organic EL display device 50a according to this embodiment will be next described. The method for manufacturing the organic EL display device 50a includes a step of forming a TFT layer.

### Step of Forming TFT Layer

The step of forming the TFT layer is a step of forming the TFT layer 20a onto the resin substrate 10. To be specific, the step of forming the TFT layer includes a step of forming insulating films, a step of forming a first metal layer, a step of forming an oxide semiconductor layer, a step of forming a gate insulating film, and a step of forming a gate electrode.

### Step of Forming Insulating Films

The surface (entire surface) of the resin substrate 10 formed on a glass substrate undergoes plasma chemical vapor deposition (CVD) for instance, to form a SiO₂ film (about 250 nm in thickness) composed of the first inorganic material, thus forming the first inorganic insulating film 11. Next, the substrate surface (entire surface) with the first inorganic insulating film 11 formed thereon undergoes plasma CVD for instance, to form a SiNx film (about 100 nm in thickness) composed of the second inorganic material.

### Step of Forming First Metal Layer

The substrate surface with the first inorganic insulating film 11 and SiNx film formed thereon undergoes photolithography for instance, to form a Mo film (the first metal film; about 200 nm in thickness), and then, the Mo film undergoes patterning to form the source electrodes 13a, drain electrodes 13b, and other components as the first metal layer. At this time, the source electrode 13a and the drain electrode 13b are formed so as to extend in parallel with each other in the first direction, and to intersect with and overlap the source region 14a and drain region 14b in plan view.

Here, in the step of forming the first metal layer, the kind of an etching gas is changed after the Mo film undergoes dry etching. That is, the SiNx film undergoes etching with a gas different from the etching gas used for the Mo film. This removes the second inorganic insulating film 12a in, for instance, the region overlapping the channel region 14c in plan view. As a result, the second inorganic insulating film 12a can remain (be formed) between the first inorganic insulating film 11 and the source electrode 13a, and between the first inorganic insulating film 11 and the drain electrode 13b. As described, the method for manufacturing the organic EL display device 50a includes one-time dry etching of the Mo film and SiNx film and hence saves the number of process steps. In addition, this manufacturing method includes etching the SiNx film to efficiently remove the Mo film directly under the oxide semiconductor layer 14, thus reducing residual Mo films.

It is noted that the kind of the etching gas is non-limiting; a commonly used gas can be used. Examples of the etching gas for the Mo film include SF₆ and Cl₂. Examples of the etching gas for the SiNx film include SF₆, Ar, and CF₄.

### Step of Forming Oxide Semiconductor Layer

The substrate surface with the source electrodes 13a, drain electrodes 13b, and other components formed thereon undergoes sputtering for instance, to form an oxide semiconductor film (about 30 nm in thickness) composed of an oxide semiconductor, such as InGaZnO₄, and then, the oxide semiconductor film undergoes patterning to form the oxide semiconductor layer 14. At this time, the oxide semiconductor layer 14 is formed so as to extend in the second direction, and to intersect with and overlap the source electrode 13a and drain electrode 13b in plan view.

### Step of Forming Gate Insulating Film

The substrate surface with the oxide semiconductor layer 14 formed thereon undergoes plasma CVD for instance, to form a silicon oxide film (about 100 nm in thickness), and then, the silicon oxide film undergoes patterning to form the gate insulating film 15. At this time, the gate insulating film 15 is formed so as to extend in the first direction, and to intersect with and overlap the channel region 14c in plan view.

### Step of Forming Gate Electrode

The substrate surface with the gate insulating film 15 formed thereon undergoes sputtering for instance, to sequentially form a titanium film (about 10 to 100 nm in thickness), an aluminum film (about 100 to 400 nm in thickness), a titanium film (about 10 to 100 nm in thickness), and other components, and then, this metal stacked film (a Ti—Al—Ti film, the second metal film) undergoes patterning to form the gate electrodes 16a, gate lines 16g, lower conductive layers, and other components as the second metal layer. At this time, the gate electrode 16a is formed onto the gate insulating film 15 so as to extend in the first direction along the gate insulating film 15, and to overlap the channel region 14c (gate insulating film 15) in plan view.

### Other Process Steps in Step of Forming TFT Layer

Other than the foregoing process steps, the step of forming the TFT layer includes a step of forming an interlayer insulating film, a step of forming contact holes, a step of forming a third metal layer, and a step of forming a flattening film.

### Step of Forming Interlayer Insulating Film

The substrate surface (entire surface) with the gate electrodes 16a and other components formed thereon undergoes plasma CVD for instance, to sequentially form a silicon oxide film (about 200 to 500 nm in thickness) and a silicon nitride film (about 50 to 400 nm in thickness), thus forming the interlayer insulating film 17. It is noted that part of the oxide semiconductor layer 14 is turned into a conductor through heating after the formation of the interlayer insulating film 17, thus forming the source regions 14a, drain regions 14b, and channel regions 14c in the oxide semiconductor layer 14.

### Step of Forming Contact Holes

The interlayer insulating film 17 undergoes patterning as appropriate on the substrate surface with the interlayer insulating film 17 formed thereon, to form contact holes.

### Step of Forming Third Metal Layer

The substrate surface with the contact holes formed therein undergoes sputtering for instance, to sequentially form a titanium film (about 10 to 100 nm in thickness), an aluminum film (about 300 to 800 nm in thickness), a titanium film (about 10 to 100 nm in thickness), and other components, and then, this metal stacked film (a Ti—Al—Ti film, the third metal film) undergoes patterning to form the source lines 18f, power supply lines 18g, upper conductive layers, and other components as the third metal layer.

### Step of Forming Flattening Film

The substrate surface with the source lines 18f, power supply lines 18g, and other components formed thereon undergoes spin coating or slit coating for instance, to form a photosensitive acrylic resin film (about 2 μm in thickness), and then, the applied film undergoes pre-baking, exposure, development, and post-baking to form the flattening film 19.

The method for manufacturing the organic EL display device 50a also includes a step of forming an organic EL element layer, and a step of forming a sealing film.

### Step of Forming Organic EL Element Layer

The organic EL element layer 30 is formed by forming, through a well-known method, the third electrodes 21, the edge cover 22, the organic EL layers 23 (the hole injection layer 1, the hole transport layer 2, the emission layer 3, the electron transport layer 4, and the electron injection layer 5), and the fourth electrode 24 onto the flattening film 19 of the TFT layer 20a formed in the step of forming the TFT layer.

### Step of Forming Sealing Film

The first process step is forming an inorganic insulating film, such as a silicon nitride film, a silicon oxide film, or a silicon oxide nitride film, onto the substrate surface with the organic EL element layer 30 formed thereon, through plasma CVD using a mask to form the first inorganic sealing film 31.

The next is forming a film of an organic resin material, such as acrylic resin, onto the substrate surface with the first inorganic sealing film 31 formed thereon, through ink-jet printing for instance, to form the organic sealing film 32.

The next is forming an inorganic insulating film, such as a silicon nitride film, a silicon oxide film, or a silicon oxide nitride film, onto the substrate with the organic sealing film 32 formed thereon, through plasma CVD using a mask to form the second inorganic sealing film 33, thus forming the sealing film 35.

The final process step is attaching a protective sheet (not shown) to the substrate surface with the sealing film 35 formed thereon, followed by laser light irradiation from the glass substrate of the resin substrate 10 to remove the glass substrate from the lower surface of the resin substrate 10, followed by attaching another protective sheet (not shown) to the lower surface of the resin substrate 10 with the glass substrate removed therefrom.

The organic EL display device 50a according to this embodiment can be manufactured through the foregoing process steps.

### Effects

The organic EL display device 50a and the method for manufacturing the same according to this embodiment can achieve the following effects.

(1) In the organic EL display device 50a, the first TFT 9a and second TFT 9b of bottom-contact structure, in which the source electrode 13a and the drain electrode 13b are disposed under the oxide semiconductor layer 14, are provided on the first inorganic insulating film 11. Moreover, the second inorganic insulating film 12a, which is formed from a SiNx film, is interposed between the first inorganic insulating film 11, which is formed from a SiO₂ film, and the source electrode 13a and drain electrode 13b, both of which are formed from a Mo film. In this structure, the Mo film, which constitutes the source electrode 13a and the drain electrode 13b, is in contact with the SiNx film, which constitutes the second inorganic insulating film 12a, but is not in contact with the SiO₂ film, which constitutes the first inorganic insulating film 11. The Mo film is hence prevented from oxidation resulting from oxygen desorption from the SiO₂ film. As a result, the source electrode 13a and the drain electrode 13b are prevented from reduction in their adhesion to the layer thereunder (the second inorganic insulating film 12a, a part of the substrate), which means that the adhesion between the source electrode 13a as well as the drain electrode 13b and the substrate improves, thus preventing a film blister (film peeling) from the substrate. As such, the organic EL display device 50a can prevent poor display, such as a bright spot resulting from a TFT defect.

(2) In the organic EL display device 50a, the second inorganic insulating film 12a, which is formed from a SiNx film, is removed from the region overlapping the channel region 14c in plan view (directly under the channel region 14c), and no second inorganic insulating film 12a remains in the region. As a result, the channel region 14c is in contact with the first inorganic insulating film 11, which is formed from a SiO₂ film, thus preventing a depression shift of the oxide semiconductor.

(3) The organic EL display device 50a, which exhibits the foregoing two effects (1) and (2), can improve its manufacture yield and reliability.

(4) The method for manufacturing the organic EL display device 50a can improve the display device without increasing the number of process steps, because the step of forming the first metal layer includes changing the kind of the etching gas after subjecting the Mo film to dry etching, that is, the step includes subjecting the Mo film and the SiNx film to one-time dry etching (i.e., forming the second inorganic insulating film 12a).

(5) The method for manufacturing the organic EL display device 50a enables the Mo film over the SiNx film to be removed efficiently by etching the SiNx film in the step of forming the first metal layer, thereby reducing residual Mo films. As a result, the waveform of a current-voltage characteristic (Id-Vg curve) resulting from such Mo film residues directly under the oxide semiconductor layer 14 exhibits a gentle slope, thereby preventing inconvenience such as increase in S-value (subthreshold coefficient) and increase in its variations.

### Second Embodiment

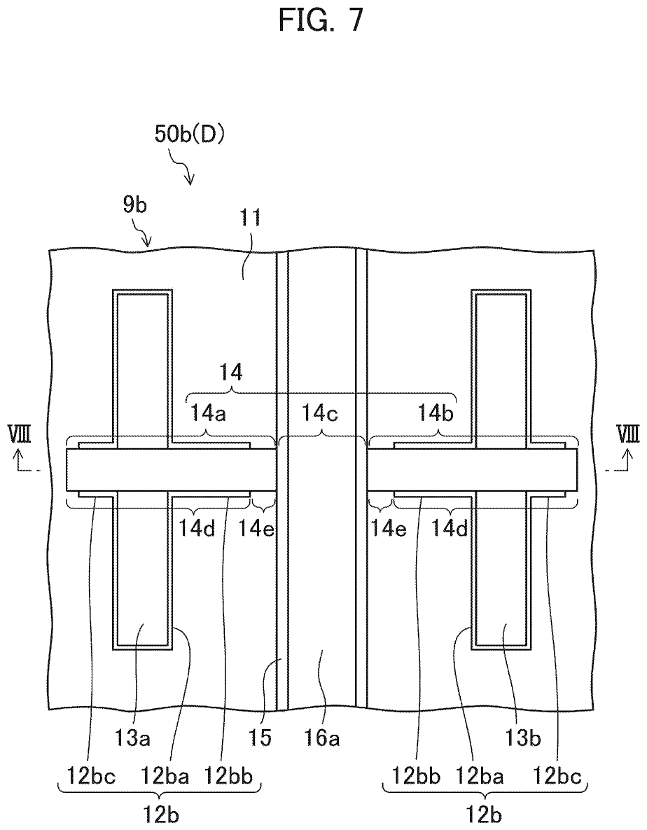

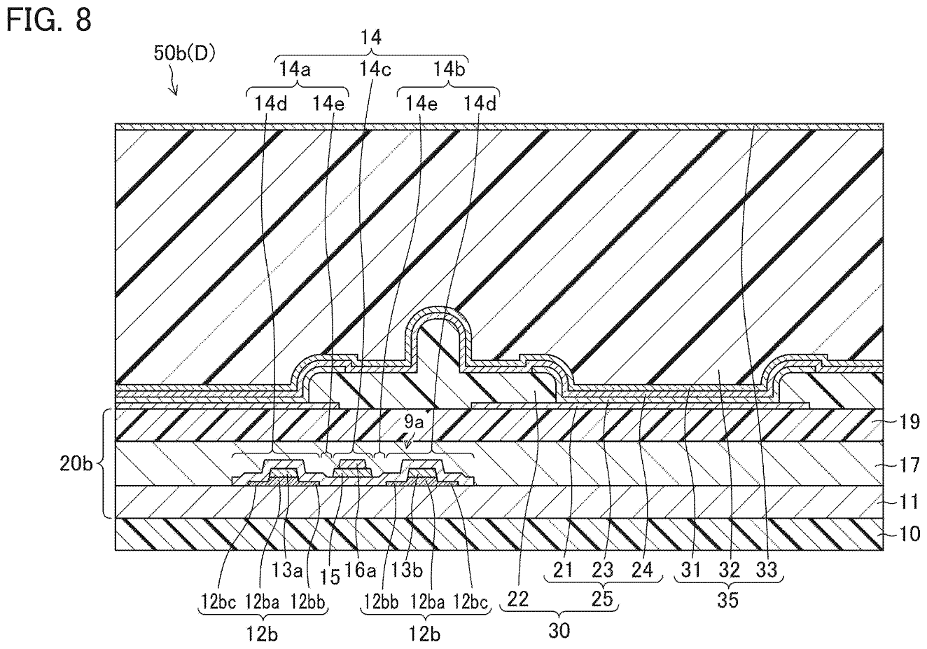

Next, a second embodiment of the disclosure will be described. FIGS. 7 and 8 illustrate a display device according to the second embodiment of the disclosure. FIG. 7 is an enlarged plan view on the periphery of a first TFT 9b, which constitutes an organic EL display device 50b according to this embodiment, and corresponds to FIG. 3. FIG. 8 is a cross-sectional view of the display region D of the organic EL display device 50b taken along line VIII-VIII in FIG. 7 and corresponds to FIG. 4.

The overall configuration of the organic EL display device 50b is the same as that of the first embodiment except a second inorganic insulating film 12b constituting a TFT layer 20b. Accordingly, the detailed description of the overall configuration will be omitted here. Further, components similar to those in the first embodiment will be denoted by the same signs, and their description will be omitted.

The second inorganic insulating film 12b of the organic EL display device 50b is different in shape and size from the second inorganic insulating film 12a of the organic EL display device 50a. To be specific, as illustrated in FIGS. 7 and 8, the second inorganic insulating film 12b includes a body portion 12ba, and a first extending portion 12bb and a second extending portion 12bc that are continuous to the body portion 12ba.

The body portion 12ba corresponds to the second inorganic insulating film 12a of the organic EL display device 50a. Thus, the configuration described about the second inorganic insulating film 12a is all applied to the body portion 12ba as well. As illustrated in FIGS. 7 and 8, the body portion12ba is provided so as to extend in the first direction, and to overlap the source electrode 13a and the drain electrode 13b in plan view.

The first extending portion 12bb and the second extending portion 12bc are each provided so as to extend in the second direction along the oxide semiconductor layer 14, as illustrated in FIGS. 7 and 8. To be specific, as illustrated in FIG. 7, the first extending portion 12bb is provided so as to protrude in a direction from a region where the source electrode 13a intersects with the source region 14a toward the channel region 14c, and a direction from a region where the drain electrode 13b intersects with the drain region 14b toward the channel region 14c. On the other hand, the second extending portion 12bc is provided so as to protrude in a direction opposite from the direction where the first extending portion 12bb protrudes from each of the intersecting regions, that is, a direction away from the channel region 14c. The first extending portion 12bb and the second extending portion 12bc overlap the source region 14a and the drain region 14b in plan view, as illustrated in FIGS. 7 and 8.

As described, in the organic EL display device 50b, the first extending portion 12bb and the second extending portion 12bc are provided, as the second inorganic insulating film 12b, also under (directly under) the source region 14a and drain region 14b not overlapping the source electrode 13a and drain electrode 13b in plan view, as illustrated in FIGS. 7 and 8. The first extending portion 12bb and the second extending portion 12bc are provided between the first inorganic insulating film 11 and the source region 14a, and between the first inorganic insulating film 11 and the drain region 14b. In other words, the source region 14a and the drain region 14b are each provided on the first extending portion 12bb and the second extending portion 12bc. It is noted that as illustrated in FIG. 8, the first extending portion 12bb and the second extending portion 12bc are thinner (shorter in the stacking direction) than the body portion 12ba. Further, the source region 14a and drain region 14b overlapping, in plan view, the first extending portion 12bb and the second extending portion 12bc as well as the body portion 12ba, being continuous between them, have a low resistance as a result of a reduction reaction resulting from hydrogen diffusion caused by the heat treatment in the subsequent step after the step of forming the oxide semiconductor layer. To be specific, as illustrated in FIGS. 7 and 8, the low-resistance region 14d is formed in the source region 14a and the drain electrode 14b, which are disposed directly on the portions 12ba, 12bb, and 12bc.

Here, in the organic EL display device 50b, the end of the first extending portion 12bb adjacent to the channel region 14c is spaced from the channel region 14c, as illustrated in FIGS. 7 and 8. Thus, each of the source region 14a and drain region 14b near the channel region 14c is a region in which no first extending portion 12bb (second inorganic insulating film 12b) is thereunder (directly thereunder; hereinafter, also referred to as a “a region absent from the second inorganic insulating film 12b”). To be specific, the regions absent from the second inorganic insulating film 12b are each formed between the first extending portion 12bb and the channel region 14c (the gate insulating film 15 disposed directly thereon). The source region 14a and drain region 14b (thereunder) overlapping the regions absent from the second inorganic insulating film 12b in plan view are in contact with the first inorganic insulating film 11, which is formed from a SiO₂ film. In addition, the source region 14a and drain region 14b overlapping the regions absent from the second inorganic insulating film 12b in plan view also have a low resistance as a result of a reduction reaction resulting from hydrogen diffusion caused by the heat treatment in the subsequent step after the step of forming the oxide semiconductor layer. To be specific, as illustrated in FIGS. 7 and 8, the low-resistance region 14d, and an intermediate-resistance (LDD) region 14e having a higher resistance than the low-resistance region 14d and a lower resistance than the channel region 14c are each formed in the source region 14a and drain region 14b overlapping the regions absent from the second inorganic insulating film 12b in plan view.

Next, a method for manufacturing the organic EL display device 50b according to this embodiment will be described. The method for manufacturing the organic EL display device 50b is different from the method for manufacturing the organic EL display device 50a in part of the step of forming the TFT layer.

### Step of Forming TFT Layer

The step of forming the TFT layer includes a step of patterning a second inorganic insulating film after the step of forming the first metal layer and before the step of forming the oxide semiconductor layer. This eliminates the need to change the kind of the etching gas after subjecting the Mo film to dry etching. Other than the foregoing, the step of forming the TFT layer is similar to that in the method for manufacturing the organic EL display device 50a.

### Step of Patterning Second Inorganic Insulating Film

After the source electrodes 13a, drain electrodes 13b, and other components are formed in the step of forming the first metal layer, the SiNx film undergoes patterning through photolithography for instance, to cause (form) the first extending portion 12bb and the second extending portion 12bc to remain as well as the body portion 12ba, which constitutes the second inorganic insulating film 12b. At this time, the first extending portion 12bb and the second extending portion 12bc are formed so as to extend in the second direction along the oxide semiconductor layer 14, and to overlap the source region 14a and drain region 14b in plan view. In addition, the first extending portion 12bb is formed in such a manner that its end adjacent to the channel region 14c does not reach the channel region 14c (i.e., in such a manner that the end is spaced from the channel region 14c).

The organic EL display device 50b according to this embodiment can be manufactured through the foregoing process steps.

### Effects

The organic EL display device 50b according to this embodiment can achieve the following effects in addition to the foregoing effects (1) to (3).

(6) The organic EL display device 50b is structured such that the first extending portion 12bb and the second extending portion 12bc are interposed between the first inorganic insulating film 11, which is formed from a SiO₂ film, and the source region 14a of the oxide semiconductor layer 14, and between the first inorganic insulating film 11 and the drain region 14b of the oxide semiconductor layer 14 while being continuous from the body portion 12ba, which constitutes the second inorganic insulating film 12b. In this structure, the first extending portion 12bb and the second extending portion 12bc, which are formed from a SiNx film, are each directly under the source region 14a and the drain region 14b as well, thereby enlarging the low-resistance region 14d.

(7) The organic EL display device 50b is structured such that the region absent from (without) the second inorganic insulating film 12b is formed between the first extending portion 12bb as well as the second extending portion 12bc and the channel region 14c (gate insulating film 15). In this structure, the LDD region 14e is formed in the source region 14a and drain region 14b overlapping the region absent from the second inorganic insulating film 12b in plan view, thereby enhancing withstanding voltage to drain voltage.

(8) In the method for manufacturing the organic EL display device 50b, the step of patterning the second inorganic insulating film includes etching the SiNx film to efficiently remove the Mo film thereon, thus reducing residual Mo films. As a result, the waveform of a current-voltage characteristic (Id-Vg curve) resulting from such Mo film residues directly under the oxide semiconductor layer 14 exhibits a gentle slope, thereby preventing inconvenience such as increase in S-value (subthreshold coefficient) and increase in its variations.

### Other Embodiments

Although the foregoing embodiments have described first and second TFTs having a single-gate structure by way of example, the first and second TFTs may have a double-gate structure.

Although the foregoing embodiments have described, by way of example, a display device provided with the first and second TFTs including an oxide semiconductor, the disclosure is also applicable to a display device of hybrid structure provided with the first TFT including a polysilicon semiconductor, and the second TFT including an oxide semiconductor.

Although the foregoing embodiments have each described, by way of example, an organic EL layer having a five-ply stacked structure of a hole injection layer, a hole transport layer, an emission layer, an electron transport layer, and an electron injection layer, the organic EL layer may have, for instance, a three-ply stacked structure of a hole injection-and-transport layer, an emission layer, and an electron transport-and-injection layer.

Although the foregoing embodiments have each described, by way of example, an organic EL display device having a third electrode as an anode, and a fourth electrode as a cathode, the disclosure is also applicable to an organic EL display device with the stacked structure of its organic EL layer being inverted: a third electrode as a cathode, and a fourth electrode as an anode.

Although the foregoing embodiments have each described, by way of example, an organic EL display device in which a TFT's electrode connected to the third electrode constitutes a drain electrode, the disclosure is also applicable to an organic EL display device in which a TFT's electrode connected to the third electrode constitutes a source electrode.

Although the foregoing embodiments have each described an organic EL display device as a display device by way of example, the disclosure is also applicable to a display device, such as a liquid crystal display device that operates in an active matrix driving scheme.

Although the foregoing embodiments have each described an organic EL display device as a display device by way of example, the disclosure is applicable to a display device provided with a plurality of light-emitting elements that are driven by current. For instance, the disclosure is applicable to a display device provided with quantum-dot light-emitting diodes (QLEDs), which are light-emitting elements including a quantum-dot-containing layer.

### INDUSTRIAL APPLICABILITY

As described above, the disclosure is useful for a display device provided with TFTs of bottom-contact structure.

1. A display device comprising:
a base substrate; and
a thin-film transistor layer provided on the base substrate, and having a stack of, in sequence, a first inorganic insulating film composed of a first inorganic material, a second inorganic insulating film composed of a second inorganic material different from the first inorganic material, a first metal film composed of a metal material containing molybdenum as a principal component, an oxide semiconductor film composed of an oxide semiconductor, a gate insulating film, and a second metal film,
the thin-film transistor layer including a thin-film transistor provided for each of subpixels constituting a display region,
the thin-film transistor including
a first electrode and a second electrode formed from the first metal film, and provided on the first inorganic insulating film so as to extend in parallel with each other in a first direction,
an oxide semiconductor layer formed from the oxide semiconductor film, and provided on the first inorganic insulating film and the first and second electrodes so as to extend in a second direction intersecting with the first and second electrodes, and
a gate electrode formed from the second metal film, and provided on the oxide semiconductor layer with the gate insulating film interposed between the gate electrode and the oxide semiconductor layer so as to extend in the first direction,
wherein the second inorganic insulating film is provided between the first inorganic insulating film and the first electrode, and between the first inorganic insulating film and the second electrode.

2. The display device according to claim 1, wherein the second inorganic insulating film overlaps a whole of the first electrode and a whole of the second electrode in a plan view.

3. The display device according to claim 1, wherein the first and second electrodes are in contact with the second inorganic insulating film.

4. The display device according to claim 1, wherein the first and second electrodes are not in contact with the first inorganic insulating film.

5. The display device according to claim 1, wherein
the oxide semiconductor layer includes
a first conductor region and a second conductor region defined so as to be spaced from each other, and electrically connected to the first electrode and the second electrode, respectively, and
a channel region defined between the first and second conductor regions, and overlapping the gate electrode in a plan view, and
the second inorganic insulating film is not in a region overlapping the channel region in the plan view.

6. The display device according to claim 5, wherein the channel region is in contact with the first inorganic insulating film.

7. The display device according to claim 5, wherein
the second inorganic insulating film includes an extending portion provided between the first inorganic insulating film and the first conductor region, and between the first inorganic insulating film and the second conductor region so as to extend in the second direction along the oxide semiconductor layer, and
an end of the extending portion adjacent to the channel region is spaced from the channel region.

8. The display device according to claim 7, wherein the extending portion overlaps the first and second conductor regions in the plan view.

9. The display device according to claim 7, wherein the extending portion is thinner than the second inorganic insulating film except the extending portion.

10. The display device according to claim 1, wherein the first inorganic material contains silicon oxide as a principal component.

11. The display device according to claim 1, wherein the second inorganic material contains silicon nitride as a principal component.

12. The display device according to claim 1, comprising:
a light-emitting element layer provided on the thin-film transistor layer, and having an arrangement of a plurality of light-emitting elements; and
a sealing film provided so as to cover the light-emitting element layer.

13. The display device according to claim 12, wherein each of the plurality of light-emitting elements is an organic electroluminescence element.

14. A method for manufacturing a display device, the display device including
a base substrate, and
a thin-film transistor layer provided on the base substrate, and having a thin-film transistor provided for each of subpixels constituting a display region,
the method comprising a step of forming the thin-film transistor layer onto the base substrate,
wherein the step of forming the thin-film transistor layer includes
a step of forming insulating films comprising sequentially forming a first inorganic insulating film composed of a first inorganic material, and a second inorganic insulating film composed of a second inorganic material different from the first inorganic material,
a step of forming a first metal layer comprising forming a first electrode and a second electrode individually so as to extend in parallel with each other in a first direction, by forming a first metal film composed of a metal material containing molybdenum as a principal component onto a substrate surface where the first and second inorganic insulating films are formed, followed by patterning the first metal film,
a step of forming an oxide semiconductor layer so as to extend in a second direction intersecting with the first and second electrodes, by forming an oxide semiconductor film composed of an oxide semiconductor onto the substrate surface where the first and second electrodes are formed, followed by patterning the oxide semiconductor film,
a step of forming a gate insulating film onto the substrate surface where the oxide semiconductor layer is formed, so as to extend in the first direction, and
a step of forming a gate electrode onto the gate insulating film by forming a second metal film onto the substrate surface where the gate insulating film is formed, followed by patterning the second metal film, and
wherein in the step of forming the first metal layer, the second inorganic insulating film is caused to remain between the first inorganic insulating film and the first electrode, and between the first inorganic insulating film and the second electrode by etching the first metal film, followed by etching the second inorganic insulating film.

15. The method for manufacturing the display device according to claim 14, wherein in the step of forming the first metal layer, the second inorganic insulating film undergoes etching with a gas different from an etching gas used for the first metal film.

16. The method for manufacturing the display device according to claim 14, wherein
the oxide semiconductor layer includes
a first conductor region and a second conductor region defined so as to be spaced from each other, and electrically connected to the first electrode and the second electrode, respectively, and
a channel region defined between the first and second conductor regions, and overlapping the gate electrode in a plan view, and
in the step of forming the first metal layer, the second inorganic insulating film in a region overlapping the channel region in a plan view undergoes removal.

17. A method for manufacturing a display device, the display device including
a base substrate, and
a thin-film transistor layer provided on the base substrate, and having a thin-film transistor provided for each of subpixels constituting a display region,
the method comprising a step of forming the thin-film transistor layer onto the base substrate,
wherein the step of forming the thin-film transistor layer includes
a step of forming insulating films comprising sequentially forming a first inorganic insulating film composed of a first inorganic material, and a second inorganic insulating film composed of a second inorganic material different from the first inorganic material,
a step of forming a first metal layer comprising forming a first electrode and a second electrode individually so as to extend in parallel with each other in a first direction, by forming a first metal film composed of a metal material containing molybdenum as a principal component onto a substrate surface where the first and second inorganic insulating films are formed, followed by patterning the first metal film,
a step of patterning the second inorganic insulating film,
a step of forming an oxide semiconductor layer so as to extend in a second direction intersecting with the first and second electrodes, by forming an oxide semiconductor film composed of an oxide semiconductor onto the substrate surface where the first and second electrodes are formed, and where the second inorganic insulating film is patterned, followed by patterning the oxide semiconductor film,
a step of forming a gate insulating film onto the substrate surface where the oxide semiconductor layer is formed, so as to extend in the first direction, and
a step of forming a gate electrode onto the gate insulating film by forming a second metal film onto the substrate surface where the gate insulating film is formed, followed by patterning the second metal film,
wherein the oxide semiconductor layer includes
a first conductor region and a second conductor region defined so as to be spaced from each other, and electrically connected to the first electrode and the second electrode, respectively, and
a channel region defined between the first and second conductor regions, and overlapping the gate electrode in a plan view, and
wherein in the step of patterning the second inorganic insulating film, the second inorganic insulating film is caused to remain between the first inorganic insulating film and the first electrode, and between the first inorganic insulating film and the second electrode, and an extending portion of the second inorganic insulating film is caused to remain between the first inorganic insulating film and the first conductor region, and between the first inorganic insulating film and the second conductor region so as to extend in the second direction along the oxide semiconductor layer, and such that an end of the extending portion adjacent to the channel region is spaced from the channel region.

18. The method for manufacturing the display device according to claim 17, wherein in the step of patterning the second inorganic insulating film, the second inorganic insulating film in a region overlapping the channel region in the plan view undergoes removal.

19. The method for manufacturing the display device according to claim 14, comprising:
a step of forming a light-emitting element layer having an arrangement of a plurality of light-emitting elements onto the thin-film transistor layer; and
a step of forming a sealing film so as to cover the light-emitting element layer.

20. The method for manufacturing the display device according to claim 19, wherein each of the plurality of light-emitting elements is an organic electroluminescence element.
